(19) United States
(12) Patent Application Publication
(10) Pub. No.: US 2007/0093004 A1
(43) Pub. Date: Apr. 26, 2007

(54) Method of manufacturing thin film transistor including ZnO thin layer

(76) Inventors: Sang Hee Park, Daejeon (KR); Chi Sun Hwang, Daejeon (KR); Hye Yong Chu, Daejeon (KR); Jeong Ik Lee, Suwon (KR); Jin Hong Lee, Daejeon (KR); Ho Sang Kwack, Cheonan-si (KR); Yong Eui Lee, Daejeon (KR); Seung Youl Kang, Daejeon (KR)

Correspondence Address: MAYER, BROWN, ROWE & MAW LLP, 1909 K STREET, N.W., WASHINGTON, DC, 20006, US

(21) Appl. No.: 11/488,895

(22) Filed: Jul. 19, 2006

(30) Foreign Application Priority Data
Oct. 25, 2005 (KR) 2005-100862
Jun. 29, 2006 (KR) 2006-59134

(51) Int. Cl. H01L 21/84

(52) U.S. Cl. 438/149

(57) ABSTRACT

Provided is a method of manufacturing a thin film transistor (TFT) including a transparent ZnO thin layer that is formed at a low temperature by causing a surface chemical reaction between precursors containing elements constituting the ZnO thin layer. The method includes the steps of: depositing a gate metal layer on a substrate and forming a gate electrode using photolithography and selective etching processes; depositing a gate insulator on the substrate having the gate electrode; forming source and drain electrodes; and depositing a ZnO thin layer on the gate insulator using a surface chemical reaction between precursors containing elements constituting the ZnO thin layer.

### CROSS-REFERENCE TO RELATED APPLICATION

This application claims priority to and the benefit of Korean Patent Application Nos. 2005-100862, filed Oct. 25, 2005 and 2006-59134, filed Jun. 29, 2006, the disclosures of which are incorporated herein by reference in their entirety.

### BACKGROUND

1. Field of the Invention

The present invention relates to a thin film transistor (TFT) including a ZnO thin layer and, more specifically, to a method of manufacturing a TFT including a transparent ZnO thin layer formed using a surface chemical reaction between precursors containing elements constituting the ZnO thin layer.

2. Discussion of Related Art

The demand for electronic devices that can use any time, any place is gradually increasing in the ubiquitous epoch. Above all, a thin film transistor (TFT) is being applied in more various fields, such as semiconductor devices, display devices, radio-frequency identification (RFID), and sensors.

In addition to an amorphous silicon (a-Si) transistor that is in the most common use, laborious research for a polycrystalline silicon (poly-Si) transistor and an organic semiconductor transistor has lately progressed. Besides, a transistor using wide-bandgap group II-VI transparent semiconductor has attracted much attention.

Among known transparent transistors, a transistor using InGaO₃(ZnO)₅, which has been proposed by Hosono group, has the best mobility characteristics (Science, vol. 300, p. 1269, 2003). Further, a transistor using a ZnO thin layer has been introduced by Wager et al (Appl. Phys. Lett, vol 82, p. 733, 2003), and a transparent transistor including an inorganic double insulating structure formed of semiconductors such as ZnO, MgZnO, and CadZnO is disclosed in U.S. Pat. No. 6,563,174 B2 by M. Kawasaki et al.

In order to manufacture the above-described known transparent transistors, a transparent semiconductor layer is mostly deposited using a pulsed laser deposition (PLD) process, a reactive solid-phase epitaxy (RSPE) process, a sputtering process, or an ion-beam sputtering process or formed through an annealing process after a deposition process. Accordingly, it is difficult to deposit the transparent semiconductor layer on a large area, and the resultant transistor is inferior in performance to conventional a-Si transistors. Further, since the transparent semiconductor layer is made by an expensive process, it cannot fulfill a need for low-cost transistors of the ubiquitous epoch.

To solve these problems, a lot of research in an organic TFT (OTFT) based on a plastic substrate using an organic semiconductor has been done in recent years. However, it is still difficult to apply the OTFT to real devices because the OTFT has bad performance. Also, since the organic semiconductor deteriorates due to environmental conditions, such as oxygen, water, and heat, it is restricted in life span. Further, an inorganic transistor based on a plastic substrate has poor device characteristics owing to a low-temperature process, so it cannot be applied to real devices.

### SUMMARY OF THE INVENTION

The present invention is directed to a method of manufacturing a thin film transistor (TFT) including a ZnO thin layer with good characteristics, which is formed at a low temperature through a simple, low-cost process.

Also, the present invention is directed to a method of manufacturing a flexible transistor array in which a semiconductor layer is formed by a low-temperature process applicable to a plastic substrate, thus resulting in a transistor that is superior to conventional OTFTs or a-Si TFTs in device characteristics and does not deteriorate under external circumstances.

Further, the present invention is directed to a method of manufacturing a transparent and flexible light emitting display, such as an organic light emitting display (OLED) on a transistor array.

One aspect of the present invention provides a method of manufacturing a transistor including the steps of: depositing a gate metal layer on a substrate and forming a gate electrode using photolithography and selective etching processes; depositing a gate insulator on the substrate having the gate electrode; depositing source and drain electrodes on a gate insulator; and depositing a ZnO thin layer on the gate insulator using a surface chemical reaction between precursors containing elements constituting the ZnO thin layer.

In one embodiment, the method may further include the step of depositing a metal layer for source and drain electrodes between the gate insulator and the ZnO thin layer and forming source and drain electrodes using photolithography and selective etching processes.

Another aspect of the present invention provides a method of manufacturing a transistor including the steps of: forming source and drain electrodes; depositing a ZnO thin layer on a substrate having formed source and drain electrodes using a surface chemical reaction between precursors containing elements constituting the ZnO thin layer; depositing a gate insulator on the substrate having the ZnO thin layer; and depositing a gate metal layer on the gate insulator and forming a gate electrode using photolithography and selective etching processes.

In one embodiment, the method may further include the step of depositing a metal layer for source and drain electrodes between the substrate and the ZnO thin layer and forming source and drain electrodes using photolithography and selective etching processes.

In another embodiment, the method may further include the step of depositing a metal layer for source and drain electrodes on the ZnO thin layer and forming source and drain electrodes using photolithography and selective etching processes.

The substrate may be formed of at least one of glass, metal foil, Si, and organic plastic.

The gate electrode and the source and drain electrodes each may include at least one of a transparent oxide electrode and a metal electrode.

The transparent oxide electrode may be formed of one of indium tin oxide (ITO), indium zinc oxide (IZO), and ZnO:Al(Ga).

Also, the metal electrode may be formed of at least one of Ag, Au, Al, Cr, Al/Cr/Al, and Ni.

In order to prevent diffusion of impurities from the substrate into devices, the method may further include the step of forming a buffer insulating layer between the substrate and the gate electrode.

The gate insulator may include one of an inorganic insulating layer, a double inorganic insulating layer, an organic insulating layer, and an organic-inorganic hybrid double layer.

The inorganic insulating layer may be formed of at least one of SiNₓ, AlON, TiO₂, AlOₓ, TaOₓ, HfOₓ, SiON, and SiO_{X}.

The gate insulator may be formed by at least one of an atomic layer deposition (ALD) process and a plasma-enhanced chemical vapor deposition (PECVD) process.

The deposition of the ZnO thin layer may include producing ZnO by causing a surface chemical reaction between a Zn-containing precursor and an O-containing precursor.

The Zn precursor may be one of diethyl zinc and dimethyl zinc.

The O-containing precursor may be one of H₂O, O₃, O₂, H2_{O}plasma, and O₂ plasma.

When the O-containing precursor is H₂O, a chamber of an ALD system may be maintained at a temperature of 70 to 150 ° C.

When the O-containing precursor is O₃, the chamber of the ALD system may be maintained at a temperature of 100 to 300 ° C.

When the O-containing precursor is O₂ plasma, the chamber of the ALD system may be maintained at a temperature of 40 to 300 ° C.

The deposition of the ZnO thin layer may include the steps of:
(a) loading the substrate having the gate electrode, the gate insulator, and the source and drain electrodes into a chamber of an ALD system maintained at a predetermined temperature; (b) injecting only a Zn precursor or both a Zn precursor and a carrier gas into the chamber to adsorb reactant of the Zn precursor on the surface of the substrate; (c) injecting N₂ or an inert gas into the chamber to remove unadsorbed molecules of the precursor reactant; (d) injecting an O-containing precursor into the chamber or directly generating plasma from an injected precursor in the chamber to cause a chemical reaction between the O-containing precursor and the Zn precursor adsorbed on the substrate; and (e) injecting N₂ or an inert gas into the chamber to remove by-products produced in the chemical reaction and the unreacted O-containing precursor.

In step (b), the Zn precursor may be one of diethyl zinc and dimethyl zinc.

Steps (a) to (e) may be repeated until the ZnO thin layer is formed to a desired thickness.

The ZnO thin layer may be formed to a thickness of 70 nm or less, and the ALD system may be maintained at a temperature of 40 to 300 ° C.

### BRIEF DESCRIPTION OF THE DRAWINGS

The above and other features and advantages of the present invention will become more apparent to those of ordinary skill in the art by describing in detail exemplary embodiments thereof with reference to the attached drawings in which:

FIGS. 1A through 1D are cross-sectional views illustrating a method of manufacturing a thin film transistor (TFT) including a ZnO thin layer grown using an atomic layer deposition (ALD) technique according to an embodiment of the present invention;

FIG. 2 is a flowchart illustrating a method of growing a ZnO thin layer included in a TFT using an ALD technique according to the present invention;

FIGS. 3A through 3D are cross-sectional views of a TFT including a ZnO thin layer grown using an ALD technique according to another embodiment of the present invention;

FIG. 4 is a graph showing the electrical characteristics of a TFT including a ZnO thin layer grown using an ALD technique according to the present invention;

FIG. 5A is an optical photograph of a quarter common intermediate format (QCIF) array according to the present invention; and

FIG. 5B is a photograph showing the drive of an active-matrix organic light emitting display (AM-OLED) that is manufactured by forming an OLED on the QCIF array shown in FIG. 5A.

### DETAILED DESCRIPTION OF EMBODIMENTS

A method of manufacturing a transistor including a ZnO thin layer grown using an atomic layer deposition (ALD) technique according to the present invention will now be described more fully hereinafter with reference to the accompanying drawings, in which exemplary embodiments of the invention are shown.

Initially, the ALD technique will be described to facilitate understanding.

The ALD technique may be greatly classified into a traveling wave reactor type ALD technique and a plasma-enhanced ALD technique.

More specifically, the plasma-enhanced ALD technique may be divided into a remote plasma ALD technique and a direct plasma ALD technique according to a plasma generator.

The present invention can employ all kinds of ALD techniques and are not restricted to specific ALD techniques. But, only a process of depositing a ZnO thin layer using a traveling wave reactor type ALD technique will be described in embodiments of the present invention for brevity.

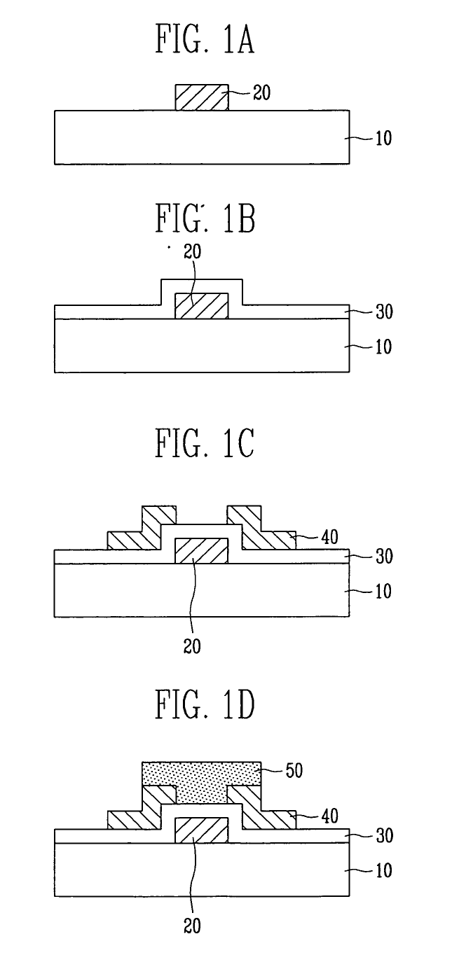

FIGS. 1A through 1D are cross-sectional views illustrating a method of manufacturing a thin film transistor (TFT) including a ZnO thin layer grown using an ALD process according to an embodiment of the present invention.

Referring to FIG. 1A, a gate metal layer is deposited on an insulating substrate 10, and a gate electrode 20 is formed in a desired shape using photolithography and selective etching processes.

The insulating substrate 10 may be formed of at least one of glass, metal foil, Si, and organic plastic.

The gate electrode 20 may be a transparent oxide electrode formed of indium tin oxide (ITO), indium zinc oxide (IZO), or ZnO:Al(Ga). Alternatively, the gate electrode 20 may be formed of at least one low-resistance metal of Ag, Au, Al, Cr, Al/Cr/Al, and Ni.

In order to prevent diffusion of impurities from the insulating substrate 10 into devices, a buffer insulating layer (not shown) may be further formed between the insulating substrate 10 and the gate electrode 20.

Referring to FIG. 1B, a gate insulator 30 is then deposited on the insulating substrate 10 having the gate electrode 20 by means of an ALD method, a plasma-enhanced chemical vapor deposition (PECVD) method, or other physical deposition methods.

The gate insulator 30 may include an inorganic insulating layer, a double inorganic insulating layer, an organic insulating layer, or an organic-inorganic hybrid double layer. The inorganic insulating layer is formed of at least one of SiNₓ, AlON, TiO₂, AlOₓ, TaOₓ, HfOₓ, SiON, and SiO_{X}. Also, when the gate insulator 30 is an organic-inorganic hybrid double layer, stress caused by the bending of a transistor can be removed during manufacture of a flexible transistor array, and a plastic substrate can be easily used by lowering the temperature at which an insulating layer is formed.

Further, when the gate insulator 30 is an inorganic insulating layer or an organic-inorganic hybrid double layer, the gate electrode 20 may be formed of a metal having an etch selectivity with respect to an insulating layer.

Referring to FIG. 1C, after a process for opening a gate electrode pad is carried out, a metal layer for source and drain electrodes is deposited on the gate insulator 30, and source and drain electrodes 40 are formed by photolithography and selective etching processes.

The metal layer for source and drain electrodes may be formed of a transparent oxide, such as ITO, IZO, ZnO:Al(Ga), or a metal, such as Al, Cr, Au, and Ag. Also, the source and drain electrodes 40 may have a double layer of the metal and the transparent oxide.

Referring to FIG. 1D, a ZnO thin layer is deposited on the source and drain electrodes 40 using an ALD process. Specifically, the ZnO thin layer is produced by a surface chemical reaction between precursors containing elements (Zn and O) constituting the ZnO layer. The precursors include a Zn precursor and an O-containing precursor. The Zn precursor is diethyl zinc or dimethyl zinc, while the O-containing precursor is H₂O, O₃, O₂, H₂O plasma, or O₂plasma.

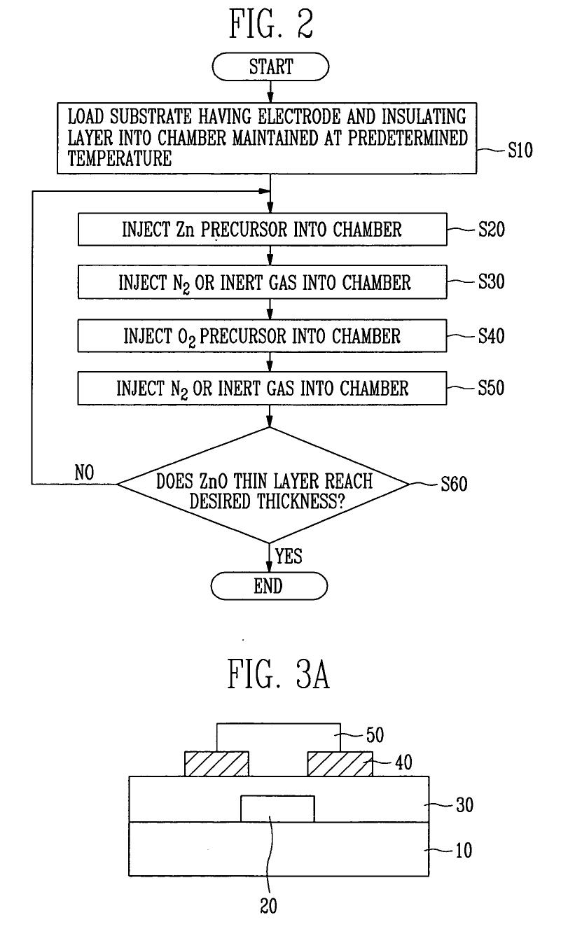

The deposition of the ZnO thin layer will be described in more detail with reference to FIG. 2.

FIG. 2 is a flowchart illustrating a method of growing a ZnO thin layer included in a TFT using an ALD technique according to the present invention.

Referring to FIG. 2, the substrate 10 where the gate electrode 20, the gate insulator 30, and the source and drain electrodes 40 are formed as described with reference to FIGS. 1A through 1C is loaded into a chamber of an ALD system that is maintained at a temperature of 70 to 150 °C. in step S10.

Thereafter, only precursors are injected into the chamber or one of diethyl zinc vapor and dimethyl zinc vapor is injected into the chamber along with a carrier gas, such as N₂ gas and Ar gas, in step S20. Thus, a Zn precursor reactant is adsorbed on the surface of the substrate 10.

Next, N₂ or an inert gas is injected into the chamber in step S30. In this process, molecules of the Zn precursor reactant, which are not adsorbed on the surface of the substrate 10, are purged and removed using the inert gas or by pumping.

Subsequently, an O-containing precursor is exposed to the substrate 10 on which the Zn precursor is adsorbed, thus causing a chemical reaction between the O-containing precursor and the Zn precursor adsorbed on the substrate 10 in step S40. Here, the O-containing precursor is one of H₂O, O₃, O₂, O₂plasma, and H₂O plasma. When the O-containing precursor is plasma, the plasma may be generated outside the chamber and then injected into the chamber or generated by applying a voltage between electrodes thus generating O₂ or H₂O plasma in situ in the reactor from water or O₂ that is directly injected into the chamber.

Afterwards, N₂ or an inert gas is injected into the chamber in step S50. Thus, by-products produced after the reaction and the unreacted O-containing precursor are purged and removed using the inert gas or by pumping.

A cycle including steps S20 through S50 may be repeated several times until a ZnO thin layer 50 is formed to a desired thickness in step 60.

In the aforementioned ALD process, the deposited thickness of the ZnO thin layer 50 depends on the number of times the cycle including steps S20 through S50 is repeated. In this case, a deposition time taken to finish one cycle depends on the amounts of precursors injected. Also, since the amounts of precursors injected are dependent on the size of the substrate 10, the resultant restricted numerical values do not matter.

In one embodiment of the present invention, when the ZnO thin layer 50 is formed using an H₂O precursor, the ZnO thin layer 50 may be formed to a thickness of 70 nm or less. Also, the chamber of the ALD system is maintained at a temperature of 70 to 150 °C., so that the amount of carrier in the ZnO thin layer 50 can be appropriately controlled. As a result, a transistor with excellent characteristics can be obtained.

Specifically, when the chamber is maintained at a temperature of 150 °C. or higher, since the amount of carrier in the ZnO thin layer 50 is too large, the transistor is normally turned on even at a turned-off state, thereby increasing a leakage current. Also, when the ZnO thin layer 50 is deposited to a thickness of 70 nm or more, the deposition process takes much time and the amount of carrier in the ZnO thin layer 50 also increases, thereby deteriorating the characteristics of the transistor.

In another embodiment of the present invention, when the ZnO thin layer 50 is formed using an 03 precursor, the chamber of the ALD system may be maintained at a temperature of 100 to 300 °C.

In still another embodiment of the present invention, when the ZnO thin layer 50 is formed using an O₂ plasma, the chamber of the ALD system may be maintained at a temperature of 40 to 300 °C.

As mentioned above, the temperature at which the chamber is maintained may be controlled according to a precursor material. In addition, the temperature at which the chamber is maintained may be controlled according to the type of the substrate 10.

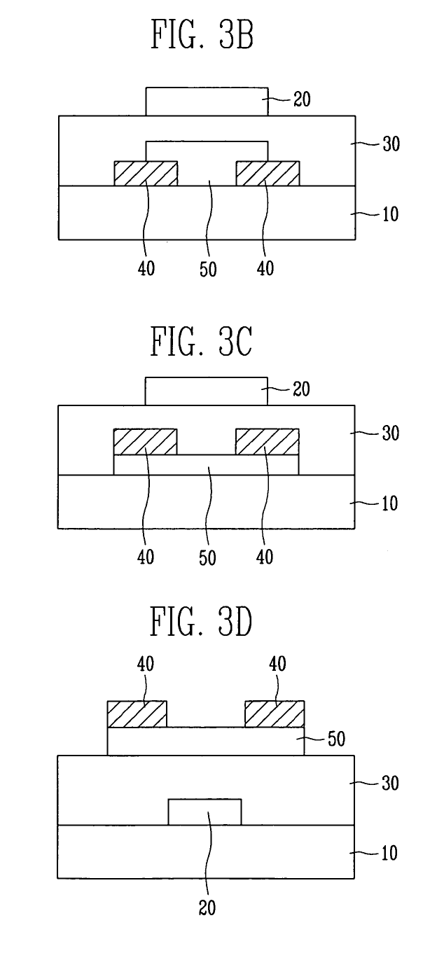

FIGS. 3A through 3D are cross-sectional views of a TFT including a ZnO thin layer grown using an ALD technique according to another embodiment of the present invention. Specifically, FIG. 3A shows an inverted planar type transistor, FIG. 3B shows a staggered type transistor, FIG. 3C shows a planar type transistor, and FIG. 3D shows an inverted staggered type transistor.

Although it is described in the embodiment that the TFT including the ZnO thin layer grown using an ALD technique according to the present invention is the inverted planar type transistor shown in FIG. 3A, the present invention is not limited to the transistor shown in FIG. 3A but can be applied to other types of transistors shown in FIGS. 3B through 3D.

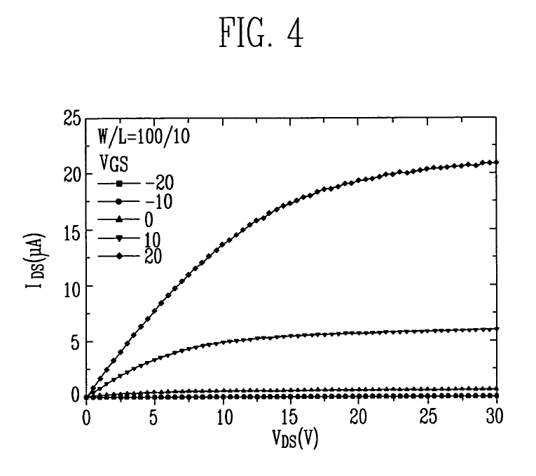

FIG. 4 is a graph showing the electrical characteristics of a TFT including a ZnO thin layer grown using an ALD technique according to the present invention.

Referring to FIG. 4, after a transistor array is manufactured such that a TFT according to the present invention has a quarter common intermediate format (QCIF) resolution, the TFT has a mobility of 1 or higher. Thus, a ZnO thin layer can be deposited without inflicting damage on an underlying thin layer (i.e., a gate insulator), so that the TFT of the present invention can have excellent characteristics.

As stated above, the ZnO thin layer using an ALD process according to the present invention is formed at a temperature of 40 to 300 ° C. Therefore, when the TFT including the ZnO thin layer is manufactured on a large-area glass or plastic substrate according to the present invention, the ZnO thin layer can have good characteristics at a low temperature without a post-processing process.

Furthermore, the resultant ZnO thin layer can be used to manufacture transistor arrays with diverse structures and applied to various devices, such as transparent display devices, flexible display devices, RFID, and sensors.

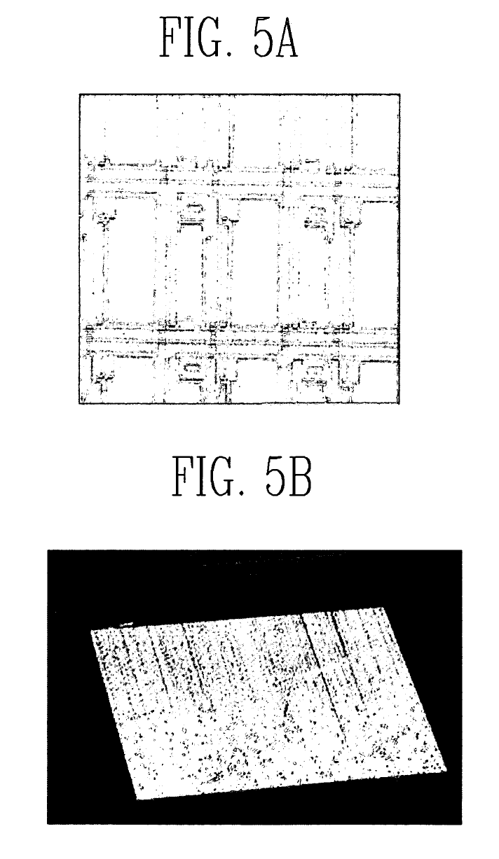

FIG. 5A is an optical photograph of a QCIF array according to an embodiment of the present invention, and FIG. 5B is a photograph showing the drive of an active-matrix organic light emitting display (AM-OLED) that is manufactured by forming an OLED on the QCIF array shown in FIG. 5A.

According to the embodiments of the present invention as described above, the following effects can be obtained.

First, since the formation of the ZnO thin layer by use of an ALD process is enabled at a temperature of 40 to 300 °C., when a TFT including the ZnO thin layer is manufactured on a large-area glass or plastic substrate, the ZnO thin layer can have excellent characteristics at a low temperature without a post-processing process.

Second, the TFT is manufactured using a transparent substrate, such as a glass substrate or a transparent plastic substrate, and a transparent oxide electrode, so that the entire TFT can constitute a transparent device. Thus, by elevating the aperture ratio of a pixel during the drive of a liquid crystal display (LCD), the luminance of the LCD can increase and power consumption can decrease.

Third, the ZnO thin layer formed according to the present invention can be used to manufacture transistor arrays with diverse structures and applied to various devices, such as transparent displays, flexible displays, RFID, and sensors.

While the invention has been shown and described with reference to certain exemplary embodiments thereof, it will be understood by those skilled in the art that various changes in form and details may be made therein without departing from the spirit and scope of the invention as defined by the appended claims.

What is claimed is:

1. A method of manufacturing a transistor, comprising the steps of:
depositing a gate metal layer on a substrate and forming a gate electrode using photolithography and selective etching processes;
forming a gate insulator on the substrate having the gate electrode;
forming source and drain electrodes on the gate insulator; and
depositing a ZnO thin layer on the gate insulator using a surface chemical reaction between precursors containing elements constituting the ZnO thin layer.

2. A method of manufacturing a transistor comprising the steps of:
depositing a ZnO thin layer on a substrate having patterned source and drain electrodes using a surface chemical reaction between precursors containing elements constituting the ZnO thin layer;
depositing a gate insulator on the substrate having the ZnO thin layer and the source and drain electrodes; and
depositing a gate metal layer on the gate insulator and forming a gate electrode using photolithography and selective etching processes.

3. A method of manufacturing a transistor comprising the steps of:
depositing a ZnO thin layer on a substrate using a surface chemical reaction between precursors containing elements constituting the ZnO thin layer;
depositing a source and drain electrode followed by patterning of source and drain electrode;
depositing a gate insulator on the ZnO thin layer and the source and drain electrodes;
and depositing a gate metal layer on the gate insulator and forming a gate electrode using photolithography and selective etching processes.

4. A method of manufacturing a transistor, comprising the steps of:
depositing a gate metal layer on a substrate and forming a gate electrode using photolithography and selective etching processes;
forming a gate insulator on the substrate having the gate electrode;
depositing a ZnO thin layer on the gate insulator using a surface chemical reaction between precursors containing elements constituting the ZnO thin layer;
and forming source and drain electrodes on the ZnO thin layer.

5. The method according to claim 1, wherein the step of depositing the ZnO thin layer comprises the step of forming ZnO using a surface chemical reaction between a Zn-containing precursor and an O-containing precursor.

6. The method according to claim 2, wherein the step of depositing the ZnO thin layer comprises the step of forming ZnO using a surface chemical reaction between a Zn-containing precursor and an O-containing precursor.

7. The method according to claim 5, wherein the Zn-containing precursor is one of diethyl zinc and dimethyl zinc.

8. The method according to claim 5, wherein the O-containing precursor is one selected from the group consisting of H₂O, O₃, O₂, H₂O plasma, and O₂ plasma.

9. The method according to claim 8, wherein when the O-containing precursor is H₂O precursor, a chamber of an atomic layer deposition (ALD) system is maintained at a temperature of 70 to 150 °C.

10. The method according to claim 8, wherein when the O-containing precursor is O₃ precursor, a chamber of an ALD system is maintained at a temperature of 100 to 300 °C.

11. The method according to claim 8, wherein when the O-containing precursor is O₂ plasma precursor, a chamber of an ALD system is maintained at a temperature of 40 to 300 ° C.

12. The method according to claim 1, wherein the step of depositing the ZnO thin layer comprises the steps of:
(a) loading the substrate having the source and drain electrodes into a chamber of an ALD system maintained at a predetermined temperature;
(b) injecting only a Zn precursor or both a Zn precursor and a carrier gas into the chamber to adsorb reactant of the Zn precursor on the surface of the substrate;
(c) injecting N₂ or an inert gas into the chamber to remove unadsorbed molecules of the precursor reactant;
(d) injecting an O-containing precursor into the chamber or directly generating plasma from an injected precursor in the chamber in situ to cause a chemical reaction between the O-containing precursor and the Zn precursor adsorbed on the substrate; and
(e) injecting N₂ or an inert gas into the chamber to remove by-products produced in the chemical reaction and the unreacted O-containing precursor.

13. The method according to claim 2, wherein the step of depositing the ZnO thin layer comprises the steps of:
(a) loading the substrate having the source and drain electrodes into a chamber of an ALD system maintained at a predetermined temperature;
(b) injecting only a Zn precursor or both a Zn precursor and a carrier gas into the chamber to adsorb reactant of the Zn precursor on the surface of the substrate;
(c) injecting N₂ or an inert gas into the chamber to remove unadsorbed molecules of the precursor reactant;
(d) injecting an O-containing precursor into the chamber or directly generating plasma from an injected precursor in the chamber to cause a chemical reaction between the O-containing precursor and the Zn precursor adsorbed on the substrate; and
(e) injecting N₂ or an inert gas into the chamber to remove by-products produced in the chemical reaction and the unreacted O-containing precursor.

14. The method according to claim 12, wherein steps (a) to (e) are repeated until the ZnO thin layer is formed to a desired thickness.

15. The method according to claim 13, wherein steps (a) to (e) are repeated until the ZnO thin layer is formed to a desired thickness.
